(19) United States
(12) Patent Application Publication
(10) Pub. No.: US 2020/0210671 A1
(43) Pub. Date: Jul. 2, 2020

(54) Optical Fingerprint Module

(71) Applicant: SHANGHAI OXI TECHNOLOGY CO., LTD, Shanghai (CN)

(72) Inventors: Yan LING, Shanghai (CN); Hong ZHU, Shanghai (CN)

(21) Appl. No.: 16/632,515

(22) PCT Filed: Jul. 26, 2017
(86) PCT No.: PCT/CN2017/094453

§ 371 Date: Jan. 20, 2020

(51) Int. Cl. G06K 9/00; H01L 27/32; H01L 51/00; G02B 27/30

(52) U.S. Cl. CPC G06K 9/0004; H01L 27/3234; H01L 27/14625; G02B 27/30; H01L 51/0097

(57) ABSTRACT

Provided is an optical fingerprint sensor module, comprising: an optical fingerprint sensor; and further comprising: a self-luminous display panel located above the optical fingerprint sensor, wherein light rays are capable of penetrating through the self-luminous display panel from top to bottom; and a light collimator panel located between the optical fingerprint sensor and the self-luminous display panel. The performance of the optical fingerprint sensor module is thus improved.

### TECHNICAL FIELD

The present disclosure generally relates to optical fingerprint identification field, and more particularly, to an optical fingerprint module.

### BACKGROUND

Fingerprint imaging recognition technology is used to realize identification by capturing fingerprint images of a person using optical fingerprint sensors and then determining whether the fingerprint images match those already stored in a system. Due to its convenience in use and uniqueness of human fingerprints, the fingerprint recognition technology has been widely applied to various fields, such as safety inspection field (for example, public security bureau or customs), entrance guard systems in buildings, or consumption goods field (for example, personal computers or mobile phones). The fingerprint recognition technology includes optical imaging, capacitive imaging, ultrasonic imaging and the like, among which, the optical fingerprint recognition technology is advantageous in imaging quality and device cost.

More content related to optical fingerprint sensors can be found in Chinese Patent Application No. CN105184230A (published on Dec. 23, 2015).

Structures of existing optical fingerprint modules need to be improved.

### SUMMARY

In embodiments of the present disclosure, an improved optical fingerprint module is provided.

In an embodiment of the present disclosure, an optical fingerprint module is provided, including: an optical fingerprint sensor; wherein the optical fingerprint module further includes: a self-luminous display panel disposed above the optical fingerprint sensor, wherein light is capable of penetrating through the self-luminous display panel from top to bottom of the self-luminous display panel; and a light collimator panel disposed between the optical fingerprint sensor and the self-luminous display panel.

Optionally, the light collimator panel has parallel upper and lower surfaces, and includes a plurality of light collimation elements that are perpendicular to the upper and lower surfaces or have a first angle α with the upper and lower surfaces, 40°≤α≤90°, wherein each of the light collimation elements includes a core layer and a skin layer surrounding the core layer, and the core layers of the light collimation elements are uniformly distributed at intervals relative to each other.

Optionally, a relative refraction index difference between the core layer and the skin layer is within a range from −10% to 10%.

Optionally, a relative refraction index difference between the core layer and the skin layer is within a range from −10% to 0.

Optionally, the core layer has an absorption rate less than 10% for visible light and infrared light, and the skin layer has an absorption rate greater than 50% for visible light and infrared light.

Optionally, a cross-sectional area of the skin layer is less than 50% of a cross-sectional area of the light collimation element.

Optionally, the light collimator panel is formed from a plurality of light collimation fibers by pressing, and each light collimation fiber is pressed to become one light collimation element.

Optionally, a separable non-opaque layer is disposed between the light collimator panel and the self-luminous display panel.

Optionally, the separable non-opaque layer includes a flexible material.

Optionally, the separable non-opaque layer includes an organic material, and thickness of the separable non-opaque layer is less than or equal to 0.2 mm.

Optionally, the separable non-opaque layer includes an ultra-thin glass, and thickness of the separable non-opaque layer is less than or equal to 0.2 mm.

Optionally, the separable non-opaque layer is disposed under the self-luminous display panel in a laminated manner.

Optionally, an optical adhesive is disposed between the separable non-opaque layer and the light collimator panel to adhere the separable non-opaque layer with the light collimator panel.

Optionally, an optical adhesive is disposed between the light collimator panel and the optical fingerprint sensor to adhere the light collimator panel with the optical fingerprint sensor.

Optionally, the self-luminous display panel is an Organic Light Emitting Diode (OLED) display panel.

Optionally, the self-luminous display panel includes a first non-opaque substrate, a second non-opaque substrate and a self-luminous circuit layer disposed between the first non-opaque substrate and the second non-opaque substrate, and the self-luminous circuit layer includes a plurality of display pixel elements each of which includes at least one opaque region and at least one non-opaque region.

Optionally, the optical fingerprint module further including a protective layer disposed on the self-luminous display panel.

Embodiments of the present disclosure may provide following advantages. In embodiments of the present disclosure, on one hand, the self-luminous display panel provides a display function. On the other hand, light reflected by a fingerprint penetrating through the self-luminous display panel can be received by the optical fingerprint sensor, thereby achieving fingerprint recognition. Therefore, the optical fingerprint module has both the display function and a fingerprint recognition function. More importantly, the light collimator panel disposed between the optical fingerprint sensor and the self-luminous display panel makes the light penetrating through the self-luminous display panel be more collimated. The light penetrating through the light collimator panel has a small angle range, and most of the light beyond the angle range is absorbed. For example, an angle between the light penetrating through the light collimator panel and the upper and lower surfaces of the light collimator panel is closer to 90° (specifically, it may be within a range from 80° to 90°), and light in other angle ranges is absorbed by the light collimator panel. This helps to improve fingerprint recognition performance of the optical fingerprint sensor.

Further, the light collimator panel has parallel upper and lower surfaces, and includes a plurality of light collimation elements that are perpendicular to the upper and lower surfaces or have a first angle α with the upper and lower surfaces, 40°≤α≤90°. Each of the light collimation elements includes a core layer and a skin layer surrounding the core layer, and the core layers of the light collimation elements are uniformly distributed at intervals relative to each other. Such a light collimator panel is more conducive to collimation of light. Besides, a fiber formation process or other processes may be used to form the light collimation element, which reduces process difficulty.

Further, a separable non-opaque layer is provided between the self-luminous display panel and the light collimator panel, and the separable non-opaque layer and the self-luminous display panel are combined together in a laminated manner. On one hand, air may be basically excluded between the separable non-opaque layer and the self-luminous display panel which thus have certain fixed intensity. That is, even during use, the separable non-opaque layer and the self-luminous display panel can still remain relatively fixed, and it is unlikely to generate relative movement. On the other hand, as the separable non-opaque layer and the self-luminous display panel are pressed together by lamination, it is easier for them to be separated from each other, compared with being adhered with each other by an adhesive layer. Therefore, if any structure below the self-luminous display panel is found to be problematic, the separable non-opaque layer may be separated from the self-luminous display panel to protect the self-luminous display panel with higher cost, so as to reduce process cost.

### BRIEF DESCRIPTION OF THE DRAWINGS

FIG. 1 schematically illustrates a structural diagram of an optical fingerprint module according to an embodiment:

FIG. 2 schematically illustrates a top view of a portion of a light collimator panel as shown in FIG. 1;

FIG. 3 schematically illustrates a sectional view of a structure as shown in FIG. 2;

FIG. 4 schematically illustrates a top view of a light collimation element;

FIG. 5 schematically illustrates a sectional view of a structure as shown in FIG. 4;

FIG. 6 schematically illustrates a structural diagram of an optical fingerprint module according to an embodiment; and

FIG. 7 schematically illustrates an enlarged view of a portion of the optical fingerprint module as shown in FIG. 6.

### DETAILED DESCRIPTION

Existing optical fingerprint modules generally have a single function and thus their application is limited.

Therefore, embodiments of the present disclosure provide an improved optical fingerprint module. The optical fingerprint module includes an optical fingerprint sensor, a self-luminous display panel and a light collimator panel. The self-luminous display panel is disposed above the optical fingerprint sensor, wherein light is capable of penetrating through the self-luminous display panel from top to bottom of the self-luminous display panel. The light collimator panel is disposed between the optical fingerprint sensor and the self-luminous display panel. Performance of the optical fingerprint module may be improved with better fingerprint recognition function and display function.

In order to clarify the object, characteristic and advantages of embodiments of the present disclosure, embodiments of present disclosure will be described clearly in detail in conjunction with accompanying drawings.

The up-down relationship in the disclosure is defined by placing the optical fingerprint module under a user's eyes. When the optical fingerprint module is placed under the eyes of the user and a display surface of the self-luminous display panel faces up, if a first structure is disposed above a second structure, it means that the first structure is closer to the user's eyes than the second structure.

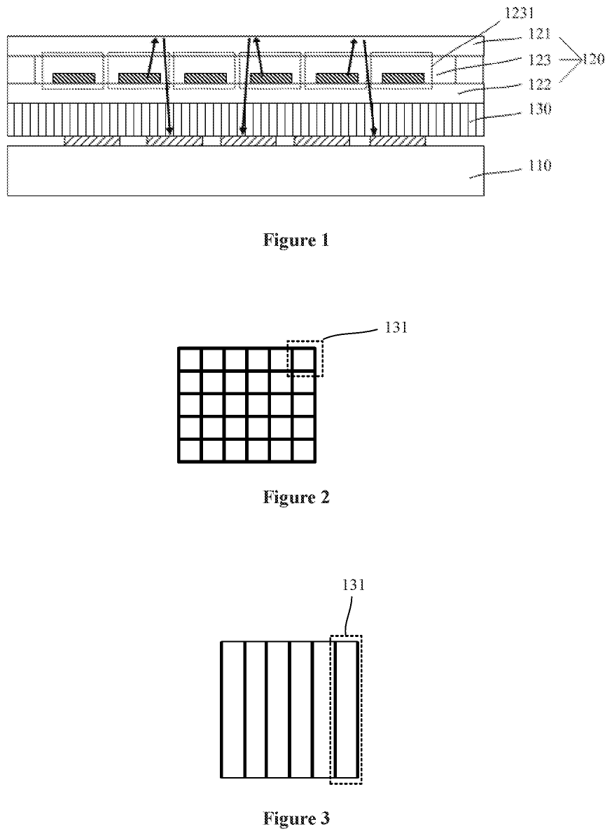

In an embodiment, an optical fingerprint module is provided. Referring to FIG. 1, the optical fingerprint module includes an optical fingerprint sensor 110, a self-luminous display panel 120 and a light collimator panel 130. The self-luminous display panel 120 is disposed above the optical fingerprint sensor 110, wherein light is capable of penetrating through the self-luminous display panel 120 from top to bottom of the self-luminous display panel. The light collimator panel 130 is disposed between the optical fingerprint sensor 110 and the self-luminous display panel 120.

A specific way of “from top to bottom” may be vertical downward, oblique downward or zigzag downward. No matter via which way of these, light can penetrate through the self-luminous display panel 120 from top of the self-luminous display panel 120 and continue to propagate downward. Besides, the self-luminous display panel 120 does not require light transmission in other directions (such as a front-rear direction and a left-right direction), and it is better to be opaque in these directions.

To enable light to penetrate through the self-luminous display panel 120 from top to bottom, a specific structure of the self-luminous display panel 120 is shown in FIG. 1 as an example. The self-luminous display panel 120 includes a first non-opaque substrate 121, a second non-opaque substrate 122 and a self-luminous circuit layer 123 disposed between the first non-opaque substrate 121 and the second non-opaque substrate 122. The optical fingerprint sensor 110 is disposed below the second transparent substrate 122.

In the self-luminous display panel 120, the self-luminous circuit layer 123 includes a plurality of display pixel elements 1231. In FIG. 1, regions where the display pixel elements 1231 are disposed and relations between adjacent display pixel elements 1231 are indicated by dashed boxes. It should be noted that, although the dashed boxes have a portion of the first non-opaque substrate 121 and second non-opaque substrate 122 therein, this is only for display convenience, and the display pixel elements 1231 do not include the first non-opaque substrate 121 and the second non-opaque substrate 122. That is, the dashed boxes in FIG. 1 are merely for schematic illustration for the display pixel elements 1231, and other embodiments below use the same display manner.

Each display pixel element 1231 includes at least one opaque region and at least one non-opaque region. As each display pixel element 1231 has a corresponding non-opaque region and an opaque region, in the embodiment, the self-luminous display panel 120 may enable light to penetrate through uniformly. The opaque region and the non-opaque region are further described below. It should be noted that a more specific structure of the display pixel element 1231 depends on a specific type of the self-luminous display panel 120.

In some embodiments, the self-luminous display panel 120 may be an OLED display panel. The display pixel element 1231 of the self-luminous circuit layer 123 may include an anode layer, a hole injection layer (HIL), a light emitting layer (EML), an electron injection layer (EIL) and a cathode layer, and may further include a hole transport layer (HTL) and an electron transport layer (ETL), and may further include structures such as thin film transistor (TFT) driving OLED, driving to metal lines and storage capacitors. A light emitting principle of the OLED display panel includes: under drive of a certain voltage, electrons and holes migrating from the cathode layer and the anode layer to the light emitting layer, and meeting in the light emitting layer to form excitons to excite light emitting molecules, and the light emitting molecules undergoing radiative relaxation and emitting visible light (or other light).

The above-mentioned structures including the light emitting layer may be disposed in the opaque region of the display pixel element 1231. On the periphery of the opaque region, the display pixel element 1231 further includes the corresponding non-opaque region. It should be noted that, in other embodiments, the non-opaque region of one display pixel element 1231 may be connected with the non-opaque region of another display pixel element 1231 to form a non-opaque region with a larger area. These two display pixel elements 1231 are usually adjacent, and a region between the two display pixel elements 1231 is also a non-opaque region, so that the three non-opaque regions can be connected into a larger non-opaque region.

Structures such as the light emitting layer, the TFT driving the OLED, the driving metal lines, and the storage capacitors of the display pixel elements 1231 need a metal layer, and therefore, the corresponding opaque regions are formed. A gap between adjacent opaque regions may be set as a non-opaque region. That is, on the basis of ensuring the corresponding structure and function, other structures of the display pixel elements 1231 may be made of a non-opaque structure as much as possible, so that more light can penetrate through the OLED display panel (generally referred to the penetration in a height direction of the display pixel elements 1231, where the height may also be referred to as thickness).

In some embodiments, the opaque regions of the display pixel elements 1231 are not opaque from top to bottom. Instead, the opaque regions have an opaque structure at their bottom (illustrated by an oblique shading portion in each display pixel element 1231 in FIG. 1). That is, structures above the light emitting layer and other structures in the opaque region are still non-opaque. For example, the structures above the light emitting layer are non-opaque, so that light emitted from the light emitting layer can reach a user's eyes upward, thereby ensuring the display function of the OLED display panel.

In some embodiments, height of the non-opaque regions is equal to height of the self-luminous circuit layer 123, thereby ensuring that light can penetrate through the self-luminous circuit layer 123 from the non-opaque regions (It should be noted that height of different portions of the self-luminous circuit layer 123 may be slightly different, but at least the height of parts of the self-luminous circuit layer 123 is equal to the height of the non-opaque regions). Further, the light penetrating through the self-luminous circuit layer 123 from the non-opaque regions ensures that the light can penetrate through the self-luminous display panel 120 from top to bottom, thereby ensuring fingerprint image acquisition of the optical fingerprint module. From above, when penetrating through the self-luminous display panel 120 (obliquely) downward, the light penetrates through the first non-opaque substrate 121, the non-opaque regions and the second non-opaque substrate 122.

The self-luminous display panel 120 further includes a sealing structure (not labeled). The sealing structure is also disposed between the first non-opaque substrate 121 and the second non-opaque substrate 122. The sealing structure together with the first non-opaque substrate 121 and the second non-opaque substrate 122 seals the self-luminous circuit layer 123 between the first non-opaque substrate 121 and the second non-opaque substrate 122.

The first non-opaque substrate 121 and the second non-opaque substrate 122 may include a transparent material, and specifically may include an inorganic glass or an organic glass, or may be a plastic product other than an organic glass.

The optical fingerprint sensor 110 may include a fingerprint sensing circuit layer (not labeled) and a base substrate (not labeled). The fingerprint sensing circuit layer includes a plurality of photosensitive pixel elements (not labeled). Each photosensitive pixel element includes a photosensitive diode or other photosensitive components, and light reflected by a fingerprint can be received by the photosensitive component. In some embodiments, the fingerprint sensing circuit layer is disposed between the second non-opaque substrate 122 and the base substrate, as shown in FIG. 1. The optical fingerprint sensor 110 may be an image sensor manufactured by a TFT process based on a glass or plastic substrate, that is, the base substrate may include glass or plastic. Alternatively, the optical fingerprint sensor 110 may be an optical sensor manufactured by a Complementary Metal-Oxide-Semiconductor Transistor (CMOS) process based on a silicon substrate, that is, the base substrate is a silicon substrate. In some embodiments, the base substrate is disposed between the second non-opaque substrate 122 and the fingerprint sensing circuit layer (for example, the optical fingerprint sensor 110 in FIG. 1 is flipped upside down). The optical fingerprint sensor 110 may be a back-illuminated image sensor manufactured by a TFT process based on a glass or plastic substrate.

The self-luminous display panel 120, the light collimator panel 130 and the optical fingerprint sensor 110 may be directly stacked. “Directly stacked” means that the self-luminous display panel 120 and the light collimator panel 130 contact with each other partly, and the light collimator panel 130 and the optical fingerprint sensor 110 contact with each other partly. When the self-luminous display panel 120, the light collimator panel 130 and the optical fingerprint sensor 110 all have flat structures that are flat on top and bottom, they may be just stacked as shown in FIG. 1.

The self-luminous display panel 120, the light collimator panel 130 and the optical fingerprint sensor 110 may be bonded through an optical adhesive layer which prevents multiple reflections and scatterings at an interface between different substrates and air, thereby avoiding a reduction in definition of fingerprint images. The optical adhesive layer may include pressure-sensitive optical adhesive, thermosensitive optical adhesive, and photosensitive optical adhesive.

When the self-luminous display panel 120 is disposed above the optical fingerprint sensor 110, and light can penetrate through the self-luminous display panel 120 from top to bottom, on one hand, the optical fingerprint module can display through the self-luminous display panel 120, on the other hand, light reflected by the fingerprint penetrating through the self-luminous display panel 120 is capable of being received by the optical fingerprint sensor 110, thereby achieving fingerprint recognition. Therefore, the optical fingerprint module has both a display function and a fingerprint recognition function.

During a process of fingerprint recognition, in some embodiments, some light emitted from the self-luminous display panel 120 is first used for the fingerprint recognition. In FIG. 1, some of the light is indicated by diagonally upward arrows (not labeled). The light reaches an upper surface of the self-luminous display panel 120, and is refracted and reflected at a surface of the fingerprint, to generate corresponding reflected light. The reflected light returns obliquely downward to the self-luminous display panel 120, further penetrates through the self-luminous display panel 120 (obliquely) downward, then penetrates through the light collimator panel 130, and reaches the optical fingerprint sensor 110 to be received by photosensitive pixels therein, thereby the fingerprint recognition being achieved by using the optical fingerprint sensor 110.

More importantly, in some embodiments, the light collimator panel 130 disposed between the optical fingerprint sensor 110 and the self-luminous display panel 120 makes light penetrating through the self-luminous display panel 120 be more collimated. The light penetrating through the light collimator panel 130 has a small angle range, and most of the light beyond the angle range is absorbed. For example, an angle between the light penetrating through the light collimator panel 130 and the upper and lower surfaces of the light collimator panel 130 is closer to 90° (the light penetrating through the light collimator panel 130 specifically includes the light penetrating through a core layer in the light collimator panel 130, where the core layer will be described below. When a length direction of the core layer is perpendicular to the upper and lower surfaces of the light collimator panel 130, an angle between the light penetrating through the core layer and the upper and lower surfaces of the light collimator panel 130 may be within a range from 80° to 90°), and light in other angle ranges is absorbed by the light collimator panel 130 (specifically, it is absorbed by a skin layer in the light collimator panel 130, where the skin layer will be described below). This helps to improve fingerprint recognition performance of the optical fingerprint sensor.

In some embodiments, the light collimator panel 130 has a special structure, which will be further described below.

FIG. 2 schematically illustrates a top view of a portion of the light collimator panel 130 as shown in FIG. 1, and FIG. 3 schematically illustrates a sectional view of the structure as shown in FIG. 2.

Referring to FIGS. 2 and 3, the light collimator panel 130 has parallel upper and lower surfaces (not labeled), and includes a plurality of light collimation elements 131 that are perpendicular to the upper and lower surfaces. In FIGS. 2 and 3, one of the light collimation elements 131 is selected and displayed by using a dashed box. Both of FIGS. 2 and 3 illustrate that the light collimation elements 131 are perpendicular to the upper and lower surfaces of the light collimator panel 130.

From the top view structure shown in FIG. 2, it can be seen that an overall top view of each light collimation element 131 is rectangular, and the light collimation elements 131 are arranged neatly in rows and columns on a top view plane. In other embodiments, an overall top view shape of the light collimation elements 131 may be a hexagon (a regular hexagon) or others. The arrangement of the light collimation elements 131 on the top view plane may have other manners.

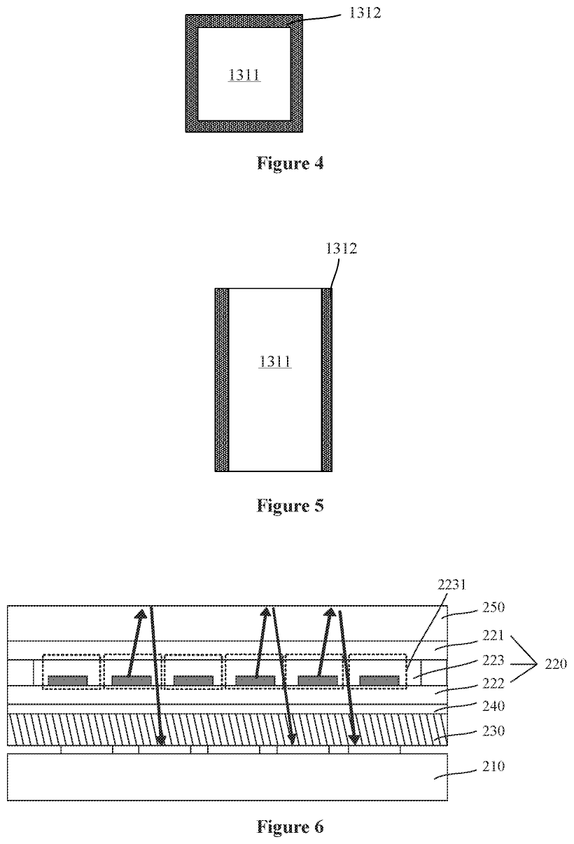

In some embodiments, each light collimation element 131 has a core layer 1311 and a skin layer 1312 (refer to FIGS. 4 and 5). In a top view, different core layers 1311 are uniformly distributed at intervals relative to each other, and the core layers 1311 are separated by the skin layers 1312, that is, the skin layers 1312 surround the core layers 1311. The core layers 1311 being uniformly distributed at intervals relative to each other corresponds to the light collimation elements 131 being arranged neatly in rows and columns as described above. When the light collimation elements 131 are perpendicular to the upper and lower surfaces of the light collimator panel 130, the core layers 1311 are also perpendicular to the upper and lower surfaces of the light collimator panel 130, specifically, the length direction of the core layers 1311 is perpendicular to the upper and lower surfaces of the light collimator panel 130.

To better display the core layer 1311 and skin layer 1312, FIG. 4 schematically illustrates a top view of one light collimation element 131, which is equivalent to enlarging one light collimation element 131 as shown in FIG. 2, and FIG. 5 schematically illustrates a sectional view of the structure as shown in FIG. 4.

In some embodiments, the light collimator panel 130 mainly uses the core layers 1311 of the light collimation elements 131 to let light go through, while the skin layers 1312 are used to absorb light. The core layers 1311 and the skin layers 1312 cooperate to achieve a light collimation effect.

From the function of the core layers 1311, it is better if the core layers 1311 have a lower absorption rate for visible light and infrared light. To ensure that intensity of the light penetrating through the core layers is sufficient, the absorption rate of the core layers 1311 for visible light and infrared light is selected to be smaller than 10%. From the function of the skin layers 1312, it is better if the skin layers 1312 have a higher absorption rate for visible light and infrared light, so as to absorb light beyond a specific angle range. To ensure effective absorption of the light beyond the specific angle range, the absorption rate of the skin layers 1312 for visible light and infrared light is selected to be greater than 50%. In this way, there are merely two situations after light (including visible light and infrared light) enters the light collimator panel 130. The first situation is the light being absorbed by the skin layers 1312, and the second situation is the light penetrating through the light collimator panel 130 along the core layers 1311.

Besides, to ensure that sufficient light can penetrate through the core layers 1311, a cross-sectional area of the skin layer 1312 is less than 50% of a cross-sectional area of the light collimation element 131.

To manufacture the light collimator panel 130 meeting the above requirements, in some embodiments, the light collimator panel 130 may be formed from a plurality of light collimation fibers by pressing, and each light collimation fiber is pressed to become one light collimation element 131. Each light collimation fiber may be formed by using an existing manufacturing process of optical fiber.

Using the existing manufacturing process of optical fiber to form the light collimation fibers (then pressing multiple light collimation fibers to form the optical collimator panel 130) is to use the existing developed optical fiber process to better form the light collimation fibers. However, in some embodiments, the light collimation fibers used to form the light collimation element 131 are different from the optical fibers. Alternatively, other methods may be used to form the light collimator panel 130, which is not limited in the present disclosure.

It should be noted that a difference between the light collimation fibers used to form the light collimation element 131 and the optical fibers lies in that the optical collimation fibers do not need to have “light total reflection property” as the optical fibers. That is, in the optical fibers, an optical fiber skin must include a relatively optically sparse medium, while an optical fiber core must include a relatively optically dense medium, and a relative refraction index difference between the optical fiber core and the optical fiber skin must be positive. However, this is not necessarily required for the light collimation fibers.

In some embodiments, a relative refraction index difference between the core layer 1311 and the skin layer 1312 is within a range from −10% to 10%. Alternatively, the optical fiber is, the relative refraction index difference between the core layer 1311 and the skin layer 1312 in the light collimation element 131 may be even completely reversed as that in the optical fibers, for example, within a range from −10% to 0, which may be more helpful for the light collimator panel 130 to achieve a better light collimation effect. It should be noted that, in the embodiment, the absorption rates of the skin layers 1312 and the core layers 1311 for visible light and infrared light are mainly considered.

In some embodiments, a relative refraction index difference Δ is a parameter representing a degree of a difference between a refraction index n1 of the core layer and a refraction index n2 of the skin layer, and is calculated based on following formula.

$$△ = \frac{{n}_{1}^{2} - {n}_{2}^{2}}{2 {n}_{1}^{2}}$$

The light collimation fibers and the optical fibers further have following important differences. Refraction indexes of the core layers 1311 and the skin layers 1312 in the light collimation fibers for visible light and near-infrared light are preferably equal or close to each other. In the light collimation fibers, it is preferable to make most of light (more than 80 percent of light) not be reflected, while the optical fibers must have total reflection property. Besides, the skin layers 1312 in the light collimation fibers have the characteristic of absorbing visible light and near-infrared light, while the optical fibers do not have the characteristic.

It can be seen from above that obliquely incident light is not significantly reflected at an interface between the core layer 1311 and the skin layer 1312 in the light collimation fiber, and is also not totally reflected, instead, it is incident from the core layer 1311 into the skin layer 1312, and absorbed by the skin layer 1312. Therefore, light having a small angle with the upper and lower surfaces of the light collimator panel 130 is absorbed by the skin 1312 after penetrating through the skin layer 1312 one or more times, while light having a large angle with the upper and lower surfaces of the light collimator panel 130 penetrates through the core layer 1311, so as to achieve a fingerprint recognition function.

As the light collimator panel 130 provided in the embodiments has the above characteristics, the light collimator panel 130 is more conducive to the light collimation effect. Besides, a corresponding optical fiber formation process or other processes may be employed to from the light collimation element 131, which reduces process difficulty.

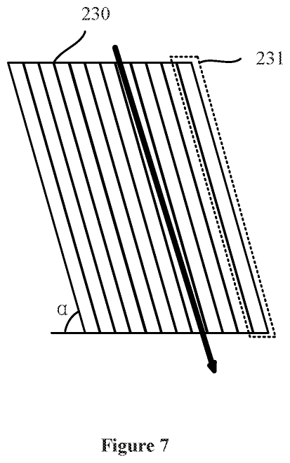

Another embodiment of the present disclosure provides an optical fingerprint module, as shown in FIG. 6.

The optical fingerprint module includes an optical fingerprint sensor 210 and a self-luminous display panel 220 disposed above the optical fingerprint sensor 210. Light can penetrate through the self-luminous display panel 220 from top to bottom of the self-luminous display panel 220. The optical fingerprint module further includes a light collimator panel 230 disposed between the optical fingerprint sensor 210 and the self-luminous display panel 220.

In some embodiments, a specific structure of the self-luminous display panel 220 is illustrated as FIG. 6. The self-luminous display panel 220 includes a first non-opaque substrate 221, a second non-opaque substrate 222 and a self-luminous circuit layer 223 disposed between the first non-opaque substrate 221 and the second non-opaque substrate 222. The optical fingerprint sensor 210 is disposed below the second non-opaque substrate 222.

In the self-luminous display panel 220, the self-luminous circuit layer 223 includes a plurality of display pixel elements 2231. Each display pixel element 2231 includes at least one opaque region and at least one non-opaque region. In some embodiments, the self-luminous display panel 220 may be an OLED display panel. The self-luminous display panel 220 may further include a sealing structure (not labeled).

In some embodiments, the optical fingerprint module further includes a protective layer 250 disposed on the self-luminous display panel 220. The protective layer 250 may be a flat substrate or have other shapes with a flat portion. The protective layer 250 may include a non-opaque material, and specifically may include inorganic glass or organic glass, or other plastic products other than organic glass.

The optical fingerprint module in the embodiment also possesses both a display function and a fingerprint recognition function.

During a process of fingerprint recognition, in some embodiments, some light emitted from the self-luminous display panel 220 is first used for the fingerprint recognition. In FIG. 6, some of the light is indicated by diagonally upward arrows (not labeled). The light reaches an upper surface of the protective layer 250, and is refracted and reflected at an interface between the protective layer 250 and a finger, to generate corresponding reflected light. The reflected light returns obliquely downward to the protective layer 250, further penetrates through the self-luminous display panel 220 (obliquely) downward, then penetrates through the light collimator panel 230, and reaches the optical fingerprint sensor 210 to be received by photosensitive pixels therein, thereby the fingerprint recognition being achieved by using the optical fingerprint sensor 210. The light collimator panel 230 makes the light penetrating through the self-luminous display panel 220 more collimated, which improves fingerprint recognition performance of the optical fingerprint sensor 210.

As mentioned in the embodiments as shown in FIG. 1 that the self-luminous display panel, the light collimator panel and the optical fingerprint sensor (referred to as the three structures hereinafter) may be directly stacked or bonded via an optical adhesive layer, where the bonding results in a better attaching to effect than the stacking. There are at least two reasons. First, as mentioned above, if no optical adhesive is used, there is likely to be an air layer between the three structures, causing a serious signal loss. Second, if an optical adhesive is not used to fix the three structures, during a subsequent process, the three structures may move relative to each other, resulting in an undesirable effect of fingerprint image acquisition. Therefore, it is better to fix the three structures to avoid air therebetween. However, when the three structures are fixed with an optical adhesive, the attaching effect is good, while cost is relatively high. This is because it is difficult to separate the three structures after the optical adhesive is cured. Therefore, if the bonding is not properly performed in any step, or if one of the structures is defective, it may cause two or three structures to be scrapped. For example, after the bonding is completed, it is found that the light collimator panel or the optical fingerprint sensor is damaged and malfunctions, which may cause the self-luminous display panel to be scrapped together. However, the self-luminous display panel has high cost. Therefore, such a fixed structure via bonding will cause an increase in process cost.

Therefore, in some embodiments, another structure and a corresponding fixing manner are proposed, as shown in FIG. 6.

In the embodiments, a separable non-opaque layer 240 is disposed between the light collimator panel 230 and the self-luminous display panel 220. The separable non-opaque layer 240 improves an assembly yield.

In the embodiments, the separable non-opaque layer 240 is laminated on a lower surface of the self-luminous display panel 220 (i.e., a lower surface of the second non-opaque substrate 222). An optical adhesive is provided between the separable non-opaque layer 240 and the light collimator panel 230 to bond the separable non-opaque layer 240 with the light collimator panel 230. An optical adhesive is also provided between the light collimator panel 230 and the optical fingerprint sensor to bond the light collimator panel 230 with the optical fingerprint sensor. Therefore, merely the separable non-opaque layer 240 and the self-luminous display panel 220 are pressed together by lamination, the separable non-opaque layer 240 and the light collimator panel 230 are bonded by the optical adhesive and the light collimator panel 230 and the optical fingerprint sensor are bonded by the optical adhesive.

The separable non-opaque layer 240 and the self-luminous display panel 220 are attached with each other by lamination, which may avoid presence of air therebetween, and provide certain fixing intensity. That is, even during use, the separable non-opaque layer 240 and the self-luminous display panel 220 can still remain relatively fixed, and it is unlikely to generate relative movement. Further, as the separable non-opaque layer 240 and the self-luminous display panel 220 are pressed together by lamination, it is easier for them to be separated from each other, compared with being adhered with each other by an adhesive layer. Therefore, if any structure below the self-luminous display panel 220 is found to be problematic, the separable non-opaque layer 240 may be separated from the self-luminous display panel 220 to protect the self-luminous display panel 220 with higher cost, so as to reduce process cost.

That is, if the optical fingerprint sensor or the light collimator panel 230 is found to be poorly adhered, or the optical fingerprint sensor or the light collimator panel 230 is found to be damaged, the separable non-opaque layer 240 may be removed from the lower surface of the self-luminous display panel 220, so that the self-luminous display panel 220 can be reused, which reduces process cost.

In some embodiments, the separable non-opaque layer 240 includes a flexible material which possesses good surface properties (such as an electrostatic adsorption function or a surface tension function).

In some embodiments, the separable non-opaque layer 240 may include an organic material, and thickness of the separable non-opaque layer 240 is less than or equal to 0.2 mm. In some embodiments, the separable non-opaque layer 240 may include ultra-thin glass, and thickness of the separable non-opaque layer 240 is less than or equal to 0.2 mm. Regardless of including an organic material or ultra-thin glass, the separable non-opaque layer 240 has the flexibility required, and possesses the properties such as electrostatic adsorption, to ensure that the self-luminous display panel 220 and the separable non-opaque layer 240 are better pressed together. When the separable non-opaque layer 240 includes an organic material, a pressing effect is better. And according to the above thickness range (50.2 mm), it can be known that the organic material is an organic thin film, and thus the separable non-opaque layer 240 may be better disposed in a laminated manner under the self-luminous display panel 220 (similar to a protective film for a mobile phone).

It should be noted that if the self-luminous display panel 220 and the light collimator panel 230 are directly laminated, an air layer is more likely to exist between them. Once there is the air layer, optical signals of fingerprint images will be greatly reduced.

Different from FIGS. 1 and 3, in the embodiment as shown in FIG. 7, although the light collimator panel 230 still includes two parallel upper and lower surfaces (not labeled), light collimator elements 231 in the light collimator panel 230 are not perpendicular to, but has a first angle α less than 90° with the upper and lower surfaces of the light collimator panel 230.

It should be noted that the first angle α is an angle between the light collimation elements 231 and the upper and lower surfaces of the light collimator panel 230, and is also an angle between a core layer (not labeled, which can be referred to the above-mentioned embodiments) in the light collimation elements 231 and the upper and lower surfaces of the light collimator panel 230, specifically being an angle between a length direction of the core layer and the upper and lower surfaces of the light collimator panel 230.

In the embodiment, 40°≤α≤90°. With this range, as shown in FIG. 7 (FIG. 7 schematically illustrates an enlarged view of a portion of the light collimator panel 230, where a black arrow represents reflected light), as more reflected light has a certain angle with the upper and lower surfaces of the light collimator panel 230. Therefore, when the light collimator elements 231 are configured to have the first angle α with the upper and lower surfaces of and the light collimator panel 230, more reflected light can penetrate through the optical collimator panel 230, and an angle difference between the reflected light after penetrating through the optical collimator panel 230 is naturally small). Therefore, the configuration helps to further improve fingerprint recognition performance of the module.

It should be noted that when the first angle α is determined, light that can penetrate through the light collimator panel 230 is usually within a range including the first angle α. For example, when the first angle α is 700, an angle range of light that can penetrate through the light collimator panel 230 may be within a range from 650 to 750.

More structures and advantages of the optical fingerprint module provided in the embodiment can be found in the above descriptions of the foregoing embodiments.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure.

1. An optical fingerprint module, comprising:
an optical fingerprint sensor;
wherein the optical fingerprint module further comprises:
a self-luminous display panel disposed above the optical fingerprint sensor, wherein light is capable of penetrating through the self-luminous display panel from top to bottom of the self-luminous display panel; and
a light collimator panel disposed between the optical fingerprint sensor and the self-luminous display panel.

2. The optical fingerprint module according to claim 1, wherein the light collimator panel has parallel upper and lower surfaces, and comprises a plurality of light collimation elements that are perpendicular to the upper and lower surfaces or have a first angle α with the upper and lower surfaces, 40°≤α≤90°, wherein each of the light collimation elements comprises a core layer and a skin layer surrounding the core layer, and the core layers of the light collimation elements are uniformly distributed at intervals relative to each other.

3. The optical fingerprint module according to claim 2, wherein a relative refraction index difference between the core layer and the skin layer is within a range from −10% to 10%.

4. The optical fingerprint module according to claim 2, wherein a relative refraction index difference between the core layer and the skin layer is within a range from −10% to 0.

5. The optical fingerprint module according to claim 2, wherein the core layer has an absorption rate less than 10% for visible light and infrared light, and the skin layer has an absorption rate greater than 50% for visible light and infrared light.

6. The optical fingerprint module according to claim 2, wherein a cross-sectional area of the skin layer is less than 50% of a cross-sectional area of the light collimation element.

7. The optical fingerprint module according to claim 2, wherein the light collimator panel is formed from a plurality of light collimation fibers by pressing, and each light collimation fiber is pressed to become one light collimation element.

8. The optical fingerprint module according to claim 1, wherein a separable non-opaque layer is disposed between the light collimator panel and the self-luminous display panel.

9. The optical fingerprint module according to claim 8, wherein the separable non-opaque layer comprises a flexible material.

10. The optical fingerprint module according to claim 8, wherein the separable non-opaque layer comprises an organic material, and thickness of the separable non-opaque layer is less than or equal to 0.2 mm.

11. The optical fingerprint module according to claim 8, wherein the separable non-opaque layer comprises an ultra-thin glass, and thickness of the separable non-opaque layer is less than or equal to 0.2 mm.

12. The optical fingerprint module according to claim 8, wherein the separable non-opaque layer is disposed under the self-luminous display panel in a laminated manner.

13. The optical fingerprint module according to claim 8, wherein an optical adhesive is disposed between the separable non-opaque layer and the light collimator panel to adhere the separable non-opaque layer with the light collimator panel.

14. The optical fingerprint module according to claim 8, wherein an optical adhesive is disposed between the light collimator panel and the optical fingerprint sensor to adhere the light collimator panel with the optical fingerprint sensor.

15. The optical fingerprint module according to claim 1, wherein the self-luminous display panel is an Organic Light Emitting Diode (OLED) display panel.

16. The optical fingerprint module according to claim 15, wherein the self-luminous display panel comprises a first non-opaque substrate, a second non-opaque substrate and a self-luminous circuit layer disposed between the first non-opaque substrate and the second non-opaque substrate, and the self-luminous circuit layer comprises a plurality of display pixel elements each of which comprises at least one opaque region and at least one non-opaque region.

17. The optical fingerprint module according to claim 1, further comprising a protective layer disposed on the self-luminous display panel.

18. The optical fingerprint module according to claim 9, wherein the separable non-opaque layer comprises an organic material, and thickness of the separable non-opaque layer is less than or equal to 0.2 mm.

19. The optical fingerprint module according to claim 13, wherein an optical adhesive is disposed between the light collimator panel and the optical fingerprint sensor to adhere the light collimator panel with the optical fingerprint sensor.
